(19) United States
(12) Patent Application Publication
(10) Pub. No.: US 2026/0214967 A1
(43) Pub. Date: Jul. 23, 2026

(54) METHOD FOR ETCHING HIGH-K LAYER OF STACKED DEVICE USING ATOMIC LAYER ETCHING PROCESS

(71) Applicant: TAIWAN SEMICONDUCTOR MANUFACTURING COMPANY, LTD., Hsinchu (TW)

(72) Inventors: Wan Ting HSU, Hsinchu City (TW); Chun-Hsien HUANG, Hsinchu City (TW)

(73) Assignee: TAIWAN SEMICONDUCTOR MANUFACTURING COMPANY, LTD., Hsinchu (TW)

(21) Appl. No.: 19/034,714

(22) Filed: Jan. 23, 2025

(51) Int. Cl. H10D 84/01; H01L 21/311

(52) U.S. Cl. CPC H10D 84/0186; H10P 50/283

(57) ABSTRACT

A method includes providing a complementary FET over a substrate. The complementary FET includes a bottom transistor over a semiconductor base portion of the substrate, and a top transistor over the bottom transistor. A first gate structure of the bottom transistor is in contact with a second gate structure of the top transistor. The substrate is thinned down to expose the semiconductor base portion. A gate via opening is formed in the semiconductor base portion to expose a high-k gate dielectric layer of the first gate structure. A deposition operation is performed to form an etchant material layer in the high-k gate dielectric layer. An etching operation is performed to remove the etchant material layer. The deposition operation and the etching operation are repeatedly performed until a work function metal layer of the first gate structure is exposed. A backside gate via is formed in the gate via opening.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are perspective views of an integrated circuit structure (or a semiconductor device) in accordance with some embodiments of the present disclosure.

FIG. 2 is a backside layout diagram of a semiconductor device in accordance with some embodiments.

FIGS. 3-10B illustrate perspective views and cross-sectional views of intermediate stages in the formation of an integrated circuit structure (or a semiconductor device) in accordance with some embodiments of the present disclosure.

FIGS. 11A-11E illustrate process flows of an atomic layer etching process in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “high-k” refers to a high dielectric constant. As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to methods of forming integrated circuit structures. More particularly, some embodiments of the present disclosure are related to method for forming stacked GAA devices including backside gate vias. During forming backside gate via openings, atomic layer etching processes are performed to remove a high-k gate dielectric layer of a gate structure of the stacked GAA device, such that the etching process can be performed precisely, and the damage to the work function metal layer of the gate structure can be avoided.

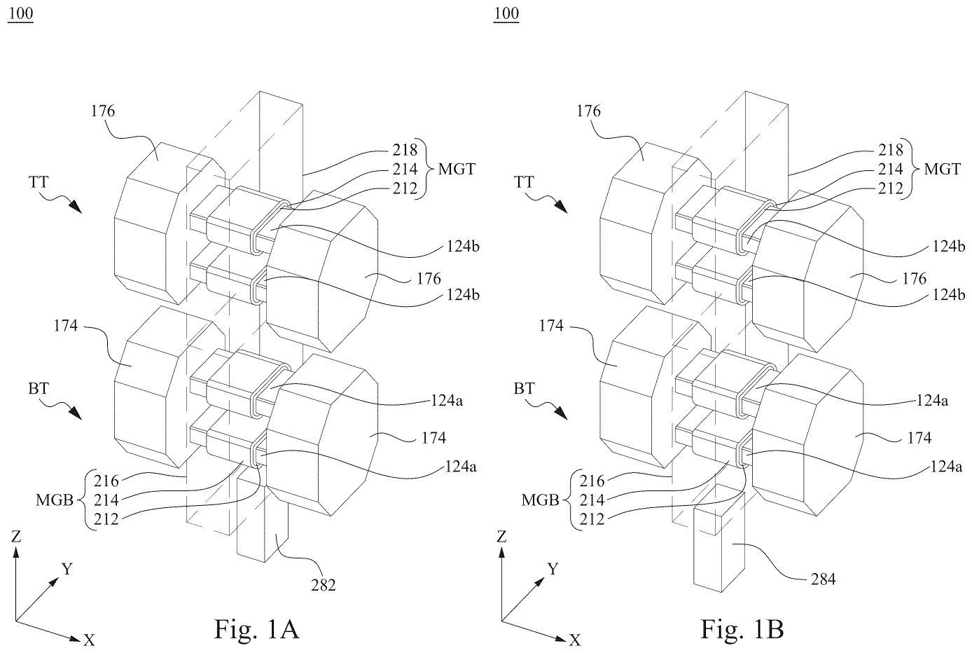

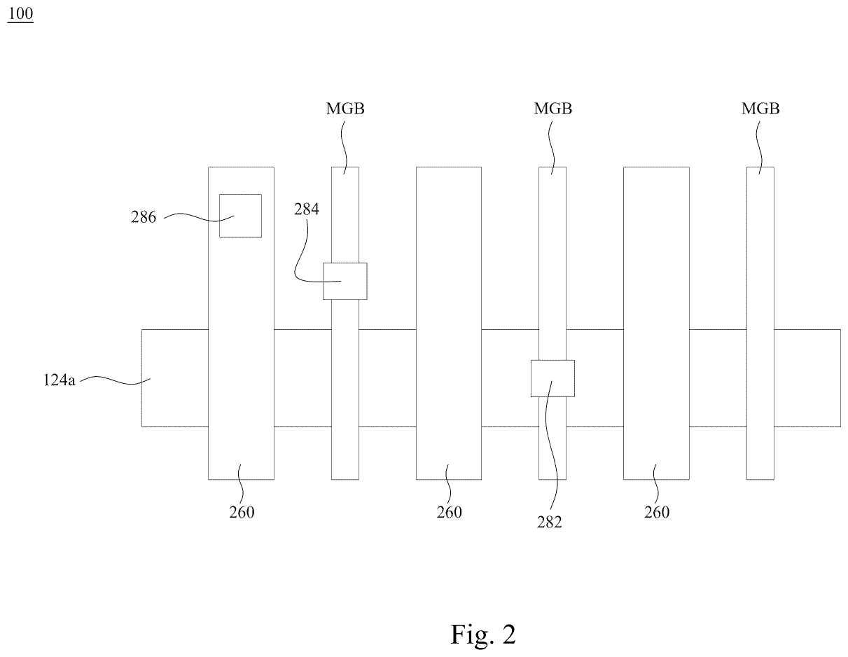

FIGS. 1A and 1B are perspective views of an integrated circuit structure (or a semiconductor device) 100 in accordance with some embodiments of the present disclosure, and FIG. 2 is a backside layout diagram of the semiconductor device 100 in accordance with some embodiments. In the present disclosure, the semiconductor device 100 is provided, and its manufacturing method will be disclosed in the following discussion. In addition to the semiconductor device 100, FIGS. 1A and 1B depict X-axis, Y-axis, and Z-axis directions. In the semiconductor device 100, a bottom transistor BT is disposed over a substrate (not shown), and a top transistor TT is disposed vertically above the bottom transistor BT. In some embodiments, the bottom transistor BT and the top transistor TT each may be a field effect transistor (FET) and may both include gate-all-around (GAA) configuration, and thus the bottom transistor BT and the top transistor TT can also be referred to as GAA FETs. The bottom transistor BT includes channel structures 124a vertically stacked one above another, a gate structure MGB wrapping around each of the channel structures 124a, and lower source/drain epitaxial structures 174 on opposite ends of each of the channel structures 124a. Similarly, the top transistor TT includes channel structures 124b vertically stacked one above another, a gate structure MGT wrapping around each of the channel structures 124b, and upper source/drain epitaxial structures 176 on opposite ends of each of the channel structures 124b.

The gate structure MGB may include an interfacial layer 212, a high-k gate dielectric layer 214, and a work function metal layer 216. Similarly, the gate structure MGT may include the interfacial layer 212, the high-k gate dielectric layer 214, and a work function metal layer 218. In some embodiments, the bottom transistor BT has a first conductivity type (e.g., p-type) and the top transistor TT has a second conductivity type (e.g., n-type) different from the first conductivity type. In some embodiments, the bottom transistor BT can be referred to as a P-FET, and the top transistor TT can be referred to as an N-FET.

The semiconductor device 100 further includes backside gate vias 282 and 284 disposed under and electrically connected to the gate structure MGB. In some embodiments, the backside gate via 282 is disposed right under the channel structures 124a as shown in FIG. 1A. In some other embodiments, the backside gate via 284 is misaligned with the channel structures 124a in the vertical direction (e.g., the Z direction) as shown in FIG. 1B.

As shown in FIG. 2, the semiconductor device 100 further includes backside source/drain contacts 260 and at least one backside source/drain via 286. The backside source/drain contacts 260 are electrically connected to the lower source/drain epitaxial structures 174. The backside source/drain via 286 is electrically connected to one of the backside source/drain contacts 260.

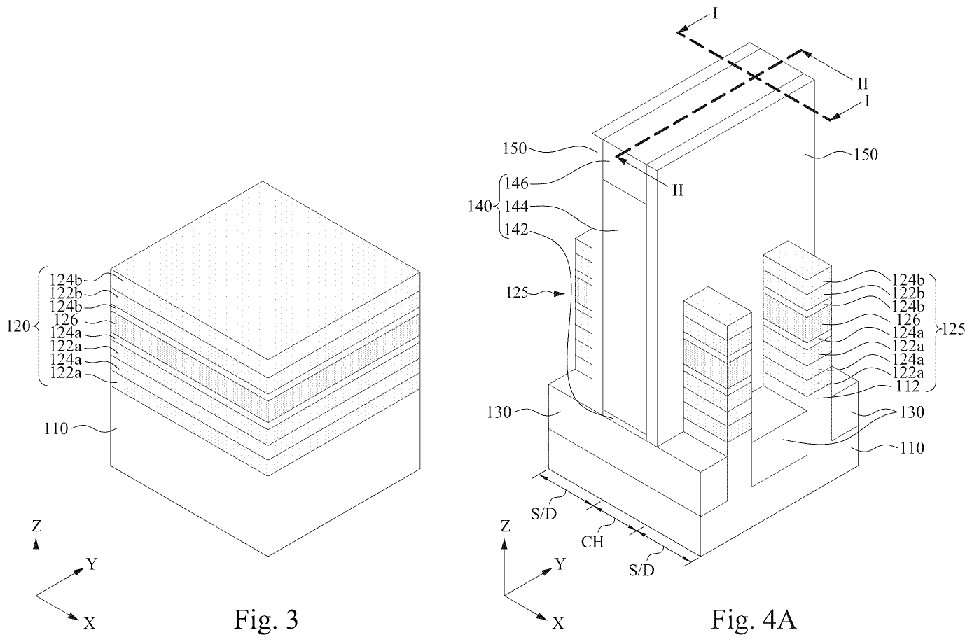

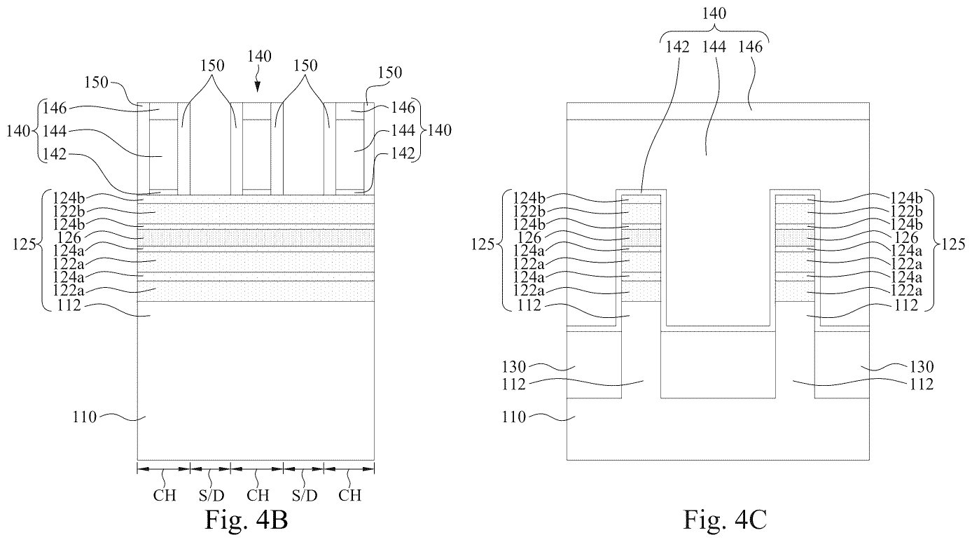

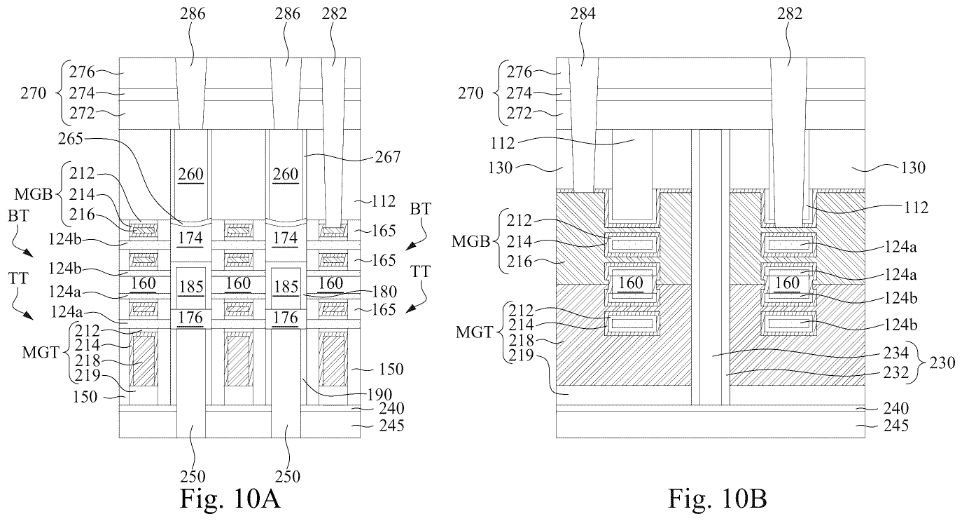

FIGS. 3-10B illustrate perspective views and cross-sectional views of intermediate stages in the formation of the integrated circuit structure (or the semiconductor device) 100 in accordance with some embodiments of the present disclosure. In some embodiments, the semiconductor device 100 in FIGS. 10A and 10B is a complementary FET (CFET) device. In addition to the semiconductor device 100, FIGS. 3 and 4A depict X-axis, Y-axis, and Z-axis directions. FIGS. 4B, 5A, 6A, 7A, 8A, 9A, 10A, and 11A are cross-sectional views of some embodiments of the semiconductor device 100 at intermediate stages along a first cut (e.g., cut I-I in FIG. 4A). FIGS. 4C, 5B, 6B, 7B, 8B, 9B, 10B, and 11B are cross-sectional views of some embodiments of the semiconductor device 100 at intermediate stages along a second cut (e.g., cut II-II in FIG. 4A). The formed devices include p-type transistors (such as p-type GAA FETs) and n-type transistors (such as n-type GAA FETs) in accordance with some exemplary embodiments. Throughout the various views and illustrative embodiments, like reference numbers are used to designate like elements. It is understood that additional operations can be provided before, during, and after the processes shown by FIGS. 3-10B, and some of the operations described below can be replaced or eliminated, for additional embodiments of the method. The order of the operations/processes may be interchangeable.

Referring to FIG. 3, a semiconductor stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The semiconductor stack 120 includes semiconductor layers 122a and 122b of a first composition interposed by semiconductor layers 124a and 124b of a second composition arranged in a stacking direction (Z-axis in this case). The semiconductor stack 120 further includes a semiconductor layer 126 between the topmost semiconductor layer 124a and the bottommost semiconductor layer 124b of a third composition. The first, second, and third compositions are different. In some embodiments, the semiconductor layers 122a, 122b, and 126 are SiGe and the semiconductor layers 124a and 124b are silicon (Si). Further, the germanium concentration of the semiconductor layer 126 is higher than the germanium concentration of the semiconductor layer 122a and 122b. However, other embodiments are possible including those that provide for a first composition, a second composition, and a third composition having different etch selectivity.

The semiconductor layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the semiconductor layers 124a and 124b to define a channel or channels of a device is further discussed below.

In FIG. 3, the semiconductor layers 124b are disposed above the semiconductor layers 124a. It is noted that two layers of the semiconductor layers 124a and two layers of the semiconductor layers 124b are arranged as illustrated in FIG. 3, which is for illustrative purposes only and not intended to be limiting beyond what is specifically recited in the claims. It can be appreciated that any number of semiconductor layers can be formed in the semiconductor stack 120; the number of layers depending on the desired number of channels regions for the transistor. In some embodiments, the number of each of the semiconductor layers 124a and 124b is between 2 and 10.

As described in more detail below, the semiconductor layers 124a and 124b may serve as channel region(s) for a subsequently-formed semiconductor device and the thickness is chosen based on device performance considerations. The semiconductor layers 122a and 122b in channel region(s) may eventually be removed and serve to define a vertical distance between adjacent channel region(s) for a subsequently-formed multi-gate device and the thickness is chosen based on device performance considerations. Accordingly, the semiconductor layers 122a and 122b may also be referred to as sacrificial layers, and the semiconductor layers 124a and 124b may also be referred to as channel layers.

By way of example, epitaxial growth of the layers of the semiconductor stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the semiconductor layers 124a and 124b include the same material as the substrate 110. In some embodiments, the semiconductor layers 122a, 122b, 124a, 124b, and 126 include a different material than the substrate 110. As stated above, in at least some examples, the semiconductor layers 122a, 122b, and 126 include an epitaxially grown silicon germanium (SiGe) layer and the semiconductor layers 124a and 124b include an epitaxially grown silicon (Si) layer. Alternatively, in some embodiments, either of the semiconductor layers 122a, 122b, 124a, 124b, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the semiconductor layers 122a, 122b, 124a, 124b, and 126 may be chosen based on providing differing oxidation and/or etching selectivity properties.

Reference is made to FIGS. 4A-4C, where FIG. 4B is a cross-sectional view taken along line I-I of FIG. 4A, FIG. 4C is a cross-sectional view taken along line II-II of FIG. 4A. Fin structures 125 extending from the substrate 110 are formed. In various embodiments, the fin structures 125 each includes a semiconductor base portion 112 formed from the substrate 110 and portions of each of the semiconductor layers of the semiconductor stack including semiconductor layers 122a, 122b, 124a, 124b, and 126. The fin structures 125 may be fabricated using suitable processes including double-patterning or multi-patterning processes.

Next, isolation structures 130 are formed to surround the fin structures 125. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, and the top surfaces of the fin structures 125 are exposed. Subsequently, the isolation structures 130 are recessed, so that the top portions of the fin structures 125 protrude higher than the top surfaces of the neighboring isolation structures 130, and the isolation structures 130 laterally surround the semiconductor base portions 112. The etching may be performed using a dry etching process or a wet etch process.

At least one dummy gate structure 140 is formed over the substrate 110 and across the fin structures 125. It is noted that in the first cut (line I-I), three dummy gate structures 140 are illustrated in FIG. 4B to clearly show the detail of the semiconductor device 100. The portions of the fin structures 125 underlying the dummy gate structure 140 may be referred to as channel regions CH. The dummy gate structure 140 may also define source/drain regions S/D of the fin structures 125, for example, the regions of the fin structures 125 adjacent and on opposite sides of the channel regions CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, dummy gate structures 140 each including a dummy gate dielectric layer 142, a dummy gate electrode layer 144 and a hard mask 146 (e.g., a nitride layer and an oxide layer) is formed.

After the formation of the dummy gate structures 140 is completed, gate spacers 150 are formed on opposite sidewalls of the dummy gate structures 140. For example, a spacer material layer is deposited on the substrate 110. The spacer material layer may be a conformal layer that is subsequently etched back to form gate sidewall spacers. In the illustrated embodiments, a spacer material layer is disposed conformally on top and sidewalls of the dummy gate structures 140. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structures 140 using suitable deposition processes. An anisotropic etching process is then performed on the deposited spacer material layer to expose portions of the fin structures 125 not covered by the dummy gate structures 140 (e.g., over the source/drain regions S/D of the fin structures 125). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity.

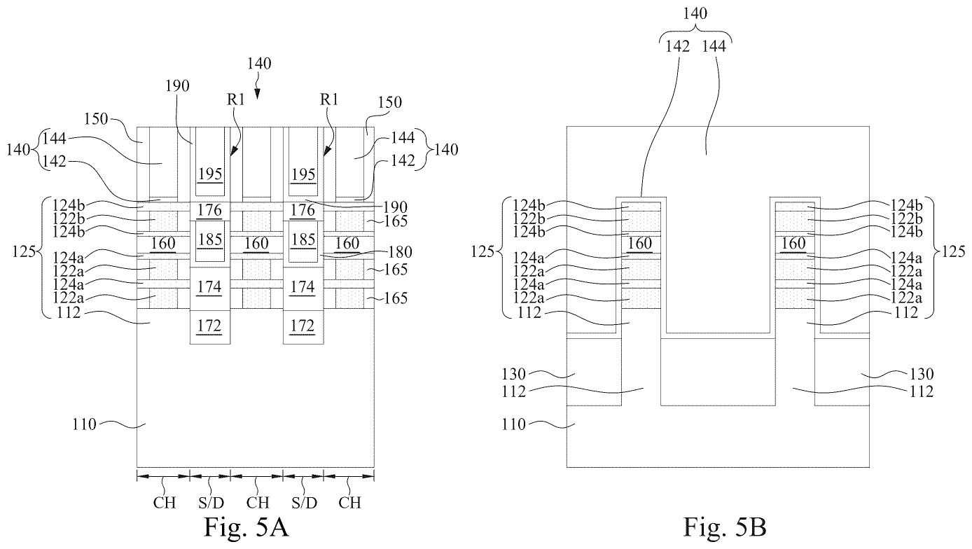

Reference is made to FIGS. 5A-5B. Exposed portions of the fin structures 125 that extend laterally beyond the gate spacers 150 (e.g., in source/drain regions S/D of the fin structures 125) are etched by using, for example, an anisotropic etching process that uses the dummy gate structure 140 and the gate spacers 150 as an etch mask, resulting in recesses R1 into the fin structures 125. After the anisotropic etching, end surfaces of the semiconductor layers 122a, 122b, 124a, 124b, and 126 and respective outermost sidewalls of the gate spacers 150 are substantially coterminous, due to the anisotropic etching. In some embodiments, the anisotropic etching may be performed by a dry chemical etch with a plasma source and a reaction gas.

The semiconductor layers 126 (see FIGS. 4A-4C) are removed, resulting in openings between the semiconductor layers 124a and 124b. Subsequently, middle dielectric isolators 160 are filled in the openings, respectively, such that the middle dielectric isolators 160 are between and in contact with the semiconductor layers 124a and 124b. For example, a dielectric material layer is formed to fill the opening. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the openings, such that portions of the deposited dielectric material layer that fill the openings are left. After the etching process, the remaining portions of the deposited spacer material in the openings are denoted as the middle dielectric isolators 160, for the sake of simplicity. The middle dielectric isolator 160 serves to isolate the semiconductor layers 124a from the semiconductor layers 124b.

The semiconductor layers 122a and 122b are then laterally or horizontally recessed by using suitable etch techniques, resulting in lateral recesses each vertically between corresponding semiconductor layers 124a and 124b. These operations may be performed by using selective etching processes. In some embodiments, the selective dry etching etches SiGe at a faster etch rate than it etches Si.

Subsequently, inner dielectric spacers 165 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Next, bottom source/drain epitaxial structures 172, lower source/drain epitaxial structures 174, a first contact etch stop layer (CESL) 180, a first interlayer dielectric (ILD) layer 185, upper source/drain epitaxial structures 176, a second CESL 190, and a second ILD layer 195 are sequentially formed in the recesses R1 of the fin structures 125. In some embodiments, semiconductor materials are deposited on the semiconductor base portions 112 to form the bottom source/drain epitaxial structures 172. The semiconductor materials include a single element semiconductor material, such as germanium (Ge) or silicon (Si), compound semiconductor materials, such as gallium arsenide (GaAs) or aluminum gallium arsenide (AlGaAs), or a semiconductor alloy, such as silicon germanium (SiGe) or gallium arsenide phosphide (GaAsP). The bottom source/drain epitaxial structures 172 have suitable crystallographic orientations (e.g., a (100), (110), or (111) crystallographic orientation). The epitaxial processes include CVD deposition techniques (e.g., vapor-phase epitaxy (VPE) and/or ultra-high vacuum CVD (UHV-CVD)), molecular beam epitaxy, and/or other suitable processes. In some embodiments, the bottom source/drain epitaxial structures 172 are intrinsic. That is, the bottom source/drain epitaxial structures 172 are undoped. The undoped bottom source/drain epitaxial structures 172 are benefit for reducing current leakage from the lower source/drain epitaxial structures 174 to the substrate 110. The bottom source/drain epitaxial structures 172 are spaced apart from the bottommost semiconductor layers 124a.

The lower source/drain epitaxial structures 174 are on the bottom source/drain epitaxial structures 172, respectively. Specifically, the lower source/drain epitaxial structures 174 are on opposite sides and connected to the semiconductor layer 124a and spaced apart from the semiconductor layers 124b. The upper source/drain epitaxial structures 176 are on opposite sides and connected to the semiconductor layer 124b and spaced apart from the semiconductor layers 124a. The lower source/drain epitaxial structures 174 and the upper source/drain epitaxial structures 176 may be formed by performing an epitaxial growth process that provides an epitaxial material on the fin structures 125. In some embodiments, the lattice constants of the lower source/drain epitaxial structures 174 are different from the lattice constant of the semiconductor layers 124a, so that the semiconductor layers 124a can be strained or stressed by the lower source/drain epitaxial structures 174 to improve carrier mobility of the semiconductor device and enhance the device performance. Similarly, the lattice constants of the upper source/drain epitaxial structures 176 are different from the lattice constant of the semiconductor layers 124b. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor layers 124a or 124b.

In some embodiments, the lower source/drain epitaxial structures 174 and the upper source/drain epitaxial structures 176 may include Ge, Si, GaAs, AlGaAs, SiGe, GaAsP, SiP, or other suitable material. The lower source/drain epitaxial structures 174 and the upper source/drain epitaxial structures 176 may be in-situ doped during the epitaxial process by introducing doping species including: p-type dopants, such as boron or BF₂; n-type dopants, such as phosphorus or arsenic; and/or other suitable dopants including combinations thereof. If the lower source/drain epitaxial structures 174 and/or the upper source/drain epitaxial structures 176 are not in-situ doped, an implantation process (i.e., a junction implant process) is performed to dope the lower source/drain epitaxial structures 174 and/or the upper source/drain epitaxial structures 176.

The first CESL 180 is formed on the substrate 110 and covers the bottom source/drain epitaxial structures 172 and the lower source/drain epitaxial structures 174. The second CESL 190 covers the upper source/drain epitaxial structures 176. In some examples, the first CESL 180 and the second CESL 190 include a silicon nitride layer, silicon oxide layer, a silicon oxynitride layer, and/or other suitable materials. The first CESL 180 and the second CESL 190 may be formed by plasma-enhanced chemical vapor deposition (PECVD) process and/or other suitable deposition or oxidation processes.

The first ILD layer 185 is formed over the first CESL 180, and the second ILD layer 195 is formed over the second CESL 190. In some embodiments, the first ILD layer 185 and the second ILD layer 195 include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the first CESL 180 and the second CESL 190. The first ILD layer 185 and the second ILD layer 195 may be deposited by a PECVD process or other suitable deposition technique.

In some examples, after depositing the second ILD layer 195, a planarization process may be performed to remove excessive materials of the second ILD layer 195. For example, a planarization process includes a chemical mechanical planarization (CMP) process which removes portions of the second ILD layer 195 and the second CESL 190 overlying the dummy gate structures 140 and planarizes a top surface of the semiconductor device 100. In some embodiments, the CMP process also removes hard masks 146 (as shown in FIGS. 4A-4C) and exposes the dummy gate electrode layers 144.

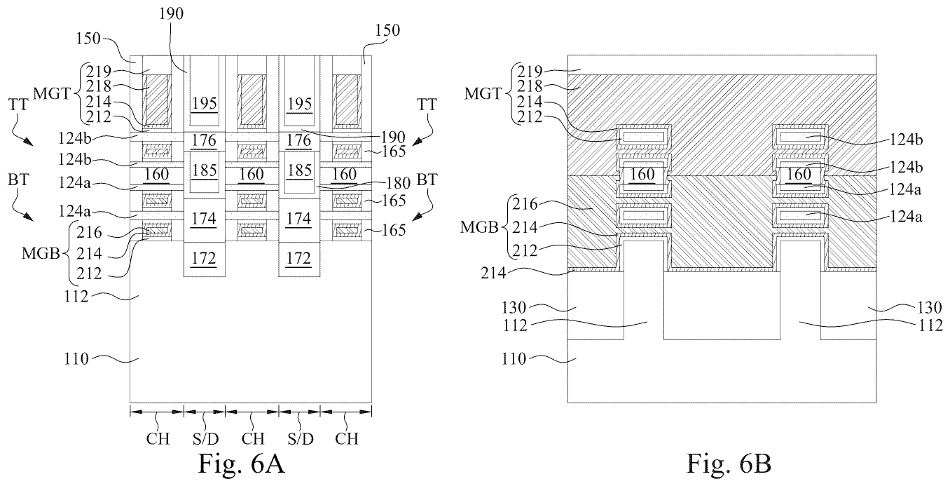

Reference is made to FIGS. 6A-6B. Thereafter, a gate replacement process is performed. Specifically, the dummy gate electrode layer 144 and the dummy gate dielectric layer 142 are removed, and then the semiconductor layers (i.e., sacrificial layers) 122a and 122b are removed. In some embodiments, the dummy gate electrode layers 144 and the dummy gate dielectric layer 142 are removed by using a selective etching process (e.g., selective dry etching, selective wet etching, or combinations thereof) that etches the materials in dummy gate electrode layers 144 and the dummy gate dielectric layer 142 at a faster etch rate than it etches other materials (e.g., the gate spacers 150), thus resulting in gate trenches between the gate spacers 150, with the semiconductor layers 122a and 122b exposed in the gate trenches. Subsequently, the semiconductor layers 122a and 122b in the gate trenches are removed by using another selective etching process that etches the semiconductor layers 122a and 122b at a faster etch rate than it etches the semiconductor layers 124a and 124b, thus forming openings between neighboring semiconductor layers 124a and 124b. In this way, the semiconductor layers 124a and 124b become nanosheets suspended over the substrate 110. This operation is also called a channel release process. In some embodiments, the semiconductor layers 124a and 124b can be interchangeably referred to as nanostructure (nanowires, nanoslabs and nanorings, nanosheet, etc., depending on their geometry). For example, in some other embodiments the semiconductor layers 124a and 124b may be trimmed to have a substantial rounded shape (i.e., cylindrical) due to the selective etching process for completely removing the semiconductor layers 124a and 124b. In that case, the resultant semiconductor layers 124a and 124b can be called nanowires.

In some embodiments, the semiconductor layers 122a and 122b are removed by using a selective dry etching process by using, for example, CF₄ as etching gases. In some embodiments, the semiconductor layers 122a and 122b are SiGe and the semiconductor layers 124a and 124b are silicon allowing for the selective removal of the semiconductor layers 122a and 122b.

Interfacial layers 212 are then formed around the semiconductor layers 124a and 124b. In some embodiments, the interfacial layer 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the semiconductor layers 124a and 124b.

Thereafter, high-k gate dielectric layers 214 are formed to cover the interfacial layers 212. High-k gate dielectrics include dielectric materials having a high dielectric constant, for example, greater than that of thermal silicon oxide (~3.9). The high-k gate dielectric layer 214 of the gate dielectric layer may include hafnium oxide (HfO₂). Alternatively, the high-k gate dielectric layer 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO₂), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, a work function metal layer 216 is deposited in the gate trenches and fills the gate trenches. The work function metal layer 216 may include work function metals to provide a suitable work function for (metal) gate structures MGB. For a p-type FET, the work function metal layer 216 may include one or more p-type work function metals (P-metal). The p-type work function metals may exemplarily include, but are not limited to, titanium nitride (TiN), titanium carbide (TiC), tungsten carbide (W₂C), tungsten nitride (W₂N), tungsten (W), Molybdenum (Mo), Molybdenum carbide (Mo₂C), Molybdenum nitride (Mo₂N), ruthenium (Ru), palladium (Pd), platinum (Pt), cobalt (Co), nickel (Ni), conductive metal oxides, and/or other suitable materials. The work function metal layer 216 may be formed by atomic layer deposition (ALD), chemical vapor deposition (CVD), and/or other suitable method. Subsequently, one or more CMP processes are performed to remove excessive gate materials.

After the formation of the work function metal layer 216, the work function metal layer 216 is etched back by using an etching process, and the top portions of the high-k gate dielectric layers 214 are exposed. Subsequently, another work function metal layer 218 is deposited in the gate trenches and over the work function metal layer 216 and fills the gate trenches. For an n-type FET, the work function metal layer 218 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

An etching back process is performed to etch back the work function metal layer 218, resulting in recesses over the etched-back work function metal layer 218. Subsequently, metal caps 219 are formed respectively atop the work function metal layer 218 by suitable process, such as CVD or ALD. In some embodiments, the metal caps 219 are formed on the work function metal layer 218 using a bottom-up approach. For example, the metal caps 219 are selectively grown on the metal surface, such as the work function metal layer 218, and thus the sidewalls of the gate spacers 150 are substantially free from the growth of the metal caps 219. The metal caps 219 may be, by way of example and not limitation, substantially fluorine-free tungsten (FFW) films having an amount of fluorine contaminants less than 5 atomic percent and an amount of chlorine contaminants greater than 3 atomic percent. The FFW films or the FFW-including films may be formed by ALD or CVD using one or more non-fluorine based tungsten precursors such as, but not limited to, tungsten pentachloride (WCl₅), tungsten hexachloride (WCl₆). In some embodiments, portions of the metal caps 219 may overflow over the high-k gate dielectric layers 214, such that the metal caps 219 may also cover the exposed surface of the high-k gate dielectric layers 214. In some embodiments, the formation of the metal caps 219 is omitted.

Therefore, the interfacial layers 212, the high-k gate dielectric layers 214, and the work function metal layer 216 form (metal) gate structures MGB, and the interfacial layers 212, the high-k gate dielectric layers 214, the work function metal layer 218, and the metal cap 219 form (metal) gate structures MGT over the gate structures MGB. The gate structure MGB is in contact with the gate structure MGT.

Further, bottom (nanostructure) transistors BT and top (nanostructure) transistors TT are formed. The top transistor TT and the bottom transistor BT in the same column form a CFET. The bottom transistors BT are over the semiconductor base portion 112 of the substrate 110 and the isolation structure 130, and the top transistors TT are directly over the bottom transistors BT, respectively. Each of the bottom transistors BT includes the semiconductor layer (or channel structure or channel layer or channel region) 124a, the lower source/drain epitaxial structures 174 on opposite sides of the channel structure 124a and connected to the channel layer 124a, and the gate structure MGB wrapping around the channel structure 124a. Each of the top transistors TT includes the semiconductor layer (or channel structure or channel layer or channel region) 124b, the upper source/drain epitaxial structures 176 on opposite sides of the channel structure 124b and connected to the channel structure 124b, and the gate structure MGT wrapping around the channel structure 124b.

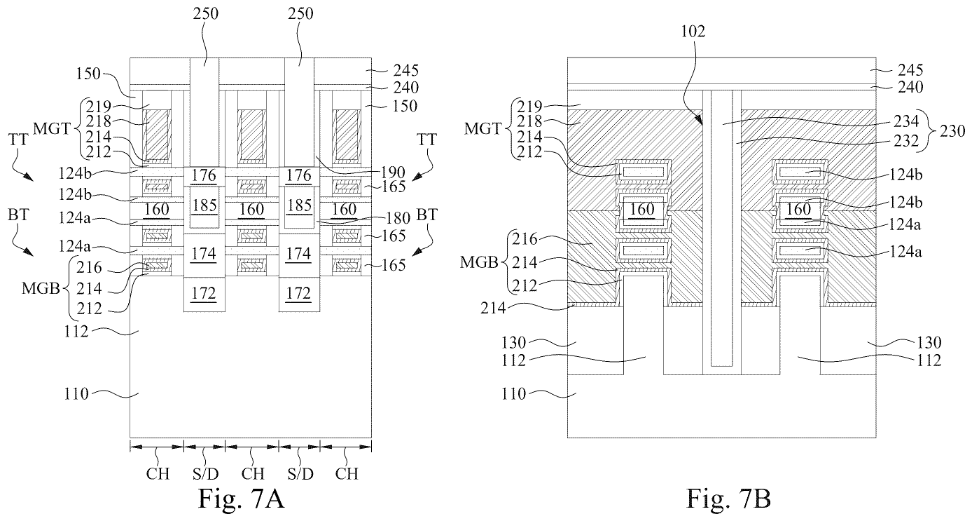

Reference is made to FIGS. 7A-7B. Optionally, a vertical local interconnect (VLI) structure 230 is formed between two pairs of the CFETs. Specifically, a trench 102 is formed in the semiconductor device 100 and between the two pairs of the CFETs. The trench 102 extends through the gate structures MGT and MGB to the top surface of the substrate 110, and some of the gate structures MGT and MGB, the gate spacers 150, the CESL 180, 190 and the ILD 185, 195 are removed.

The VLI structure 230 is formed to provide a vertical connection between the upper source/drain epitaxial structure 176 of the top transistor TT and the lower source/drain epitaxial structure 174 of the bottom transistor BT in the same column. The function of the VLI structure 230 is to reduce the parasitic resistance and capacitance that can occur when the source and drain regions are connected horizontally using metal lines. The VLI structure 230 provides a shorter and more direct path for the current to flow, which reduces the resistance and improves the performance of the device. In some embodiments, the VLI structure 230 can be interchangeably referred to as metal-like defined (MD) local interconnect (MDLI).

As illustrated in FIGS. 7A-7B, a dielectric liner 232 is formed to line sidewalls and bottom of the trench 102. In some embodiments, the dielectric liner 232 may be an oxygen-free liner. In some embodiments, the dielectric liner 232 may include silicon nitride formed by a deposition process. Subsequently, a conductive material 234 is formed in a remainder of the trench 102 and over the dielectric liner 232. The conductive material 234 may include a low resistivity conductor material, for example, having metal resistivity less than 48μΩ·cm. After the conductive material 234 are formed, the dielectric liner 232 and the conductive material 234 are polished by one or more polish process(es). The VLI structure 230 includes the dielectric liner 232 and the conductive material 234 having top surfaces level with the metal caps 219.

Next, a third CESL 240 and a third ILD layer 245 are formed over the gate structures MGT, the VLI structure 230, and the second ILD layer 195. Openings are then formed in third ILD layer 245, the third CESL 240, and the second ILD layer 195. The opening exposes the upper source/drain epitaxial structures 176. Front-side source/drain contacts 250 are then respectively formed in the openings. In some embodiments, prior to the formation of the front-side source/drain contacts 250, metal alloy layers are formed in the openings and on the exposed portions of the upper source/drain epitaxial structures 176. Each of the front-side source/drain contacts 250 is connected to the upper source/drain epitaxial structure 176. One of the front-side source/drain contacts 250 is further connected to the VLI structure 230. Formation of the front-side source/drain contacts 250 includes depositing one or more conductive (e.g., metal) materials overfilling the openings and then performing a CMP process to remove excessive metal materials outside the openings.

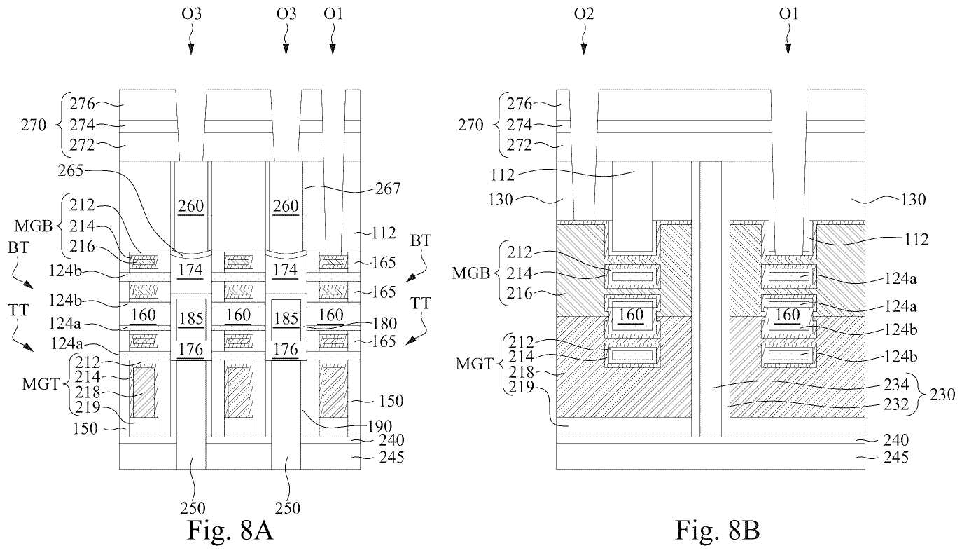

Reference is made to FIGS. 8A-8B. The semiconductor device 100 is flipped upside down, such that a backside surface of the substrate 110 faces upwards. The substrate 110 is thinned down or removed to expose the bottom surface of the isolation structure 130 and the semiconductor base portions 112. In some embodiments, the bottom portion of the dielectric liner 232 of the VLI structure 230 is also removed to expose the conductive material 234. In some embodiments, thinning is accomplished by a CMP process, a grinding process, or the like.

Openings are formed in the semiconductor base portions 112, and the bottom source/drain epitaxial structures 172 are removed. Backside source/drain contacts 260 are subsequently formed through in the semiconductor base portions 112 and electrically coupled to the lower source/drain epitaxial structures 174 and/or the VLI structure 230. Therefore, one of the upper source/drain epitaxial structures 176 can be electrically connected to one of the lower source/drain epitaxial structures 174 by the VLI structure 230. In some embodiments, dielectric liners 267 are formed to line the sidewalls of the openings prior to forming the backside source/drain contacts 260. Further, after the openings are formed, metal alloy layers 265 may be formed in the openings and on the exposed surface of the lower source/drain epitaxial structures 174. Therefore, the backside source/drain contacts 260 are in contact with the metal alloy layers 265, respectively.

A dielectric structure 270 is then formed to cover a backside of the semiconductor device 100, i.e., to cover the semiconductor base portions 112, the isolation structures 130, and the backside source/drain contacts 260. In some embodiments, the dielectric structure 270 includes a first dielectric layer 272, a second dielectric layer 274 over the first dielectric layer 272, and a third dielectric layer 276 over the second dielectric layer 274. The first dielectric layer 272, the second dielectric layer 274, and the third dielectric layer 276 may include a silicon-containing material, such as silicon nitride, silicon oxide, amorphous silicon, or other suitable material. For example, the first dielectric layer 272 and the third dielectric layer 276 are silicon oxide, and the second dielectric layer 274 is silicon nitride. The first dielectric layer 272, the second dielectric layer 274, and the third dielectric layer 276 have different material characterization, such that the first dielectric layer 272, the second dielectric layer 274, and the third dielectric layer 276 are patterned by different etching processes.

Subsequently, gate via openings O1 and O2 are formed in the dielectric structure 270 and extend to the isolation structure 130 or the semiconductor base portion 112. For example, the gate via opening O1 passes through one of the semiconductor base portions 112 as shown in FIGS. 8A and 8B, and gate via openings O2 passes through the isolation structure 130 as shown in FIG. 8B. The gate via openings O1 and O2 expose the high-k gate dielectric layers 214 of the gate structures MGB. In some embodiments, source/drain openings O3 are formed in the dielectric structure 270, the semiconductor base portions 112 and expose the backside source/drain contacts 260. The gate via openings O1 and O2 and the source/drain openings O3 may be formed by using a single or multiple etching process(es).

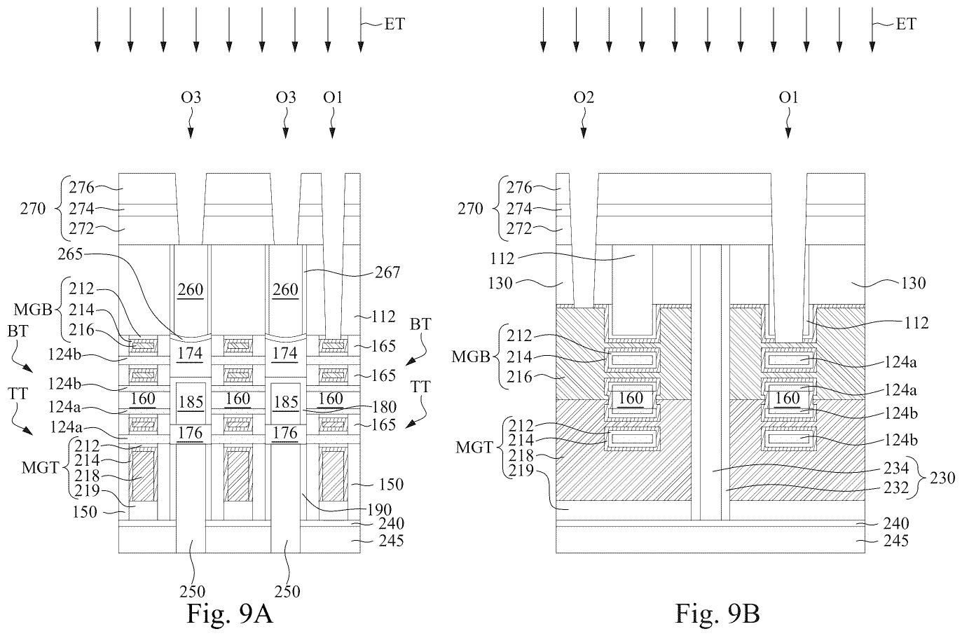

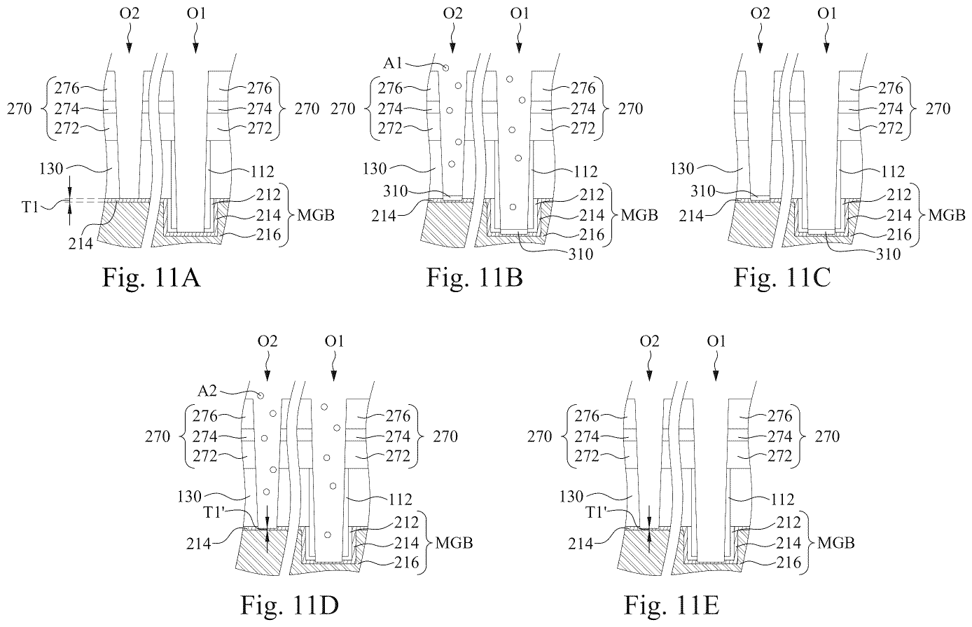

Reference is made to FIGS. 9A-9B. The high-k gate dielectric layers 214 exposed by the gate via openings O1 and O2 are removed by using an etching process ET. During the etching of the high-k gate dielectric layers 214, if the high-k gate dielectric layers 214 exposed by the openings O1 and O2 are not removed clearly, the following formed backside gate vias 282 and 284 (see FIG. 10B) may suffer high electrical resistance to the gate structure MGB. On the contrary, if the high-k gate dielectric layers 214 are over etched, the work function metal layer 216 under the high-k gate dielectric layers 214 may be damaged by the etching process. The damaged work function metal layer 216 may cause threshold voltage shift issues and/or material degradation issues of the gate structure MGB. Therefore, in some embodiments, the etching process ET is an Atomic Layer Etch (ALE) process to perform precise control over the etching of the high-k gate dielectric layers 214. The ALE process may remove the high-k gate dielectric layers 214 layer-by-layer or a few layers per cycle. The etching process ET is illustrated in further detail in FIGS. 11A-11E. The etching process ET may include performing multiple cycles, such as in a range from 2 cycles to 100 cycles. A cycle of the etching process ET may include sequentially flowing a reactant gas (FIG. 11B), such as a fluoride gas; purging (FIG. 11C) the reactant gas; flowing an etching gas (FIG. 11D), such as chlorine-containing gas; and purging (FIG. 11E) the etching gas.

Atomic layer etching (ALE) is an etch process for removing a thin layer of material by plural cycles. During each cycle of the ALE process, a thickness of the removed layer is approximately one to several atoms thick. An etchant species is disposed over a layer of a surface of a material to be etched. The etchant species bonds with surface atoms of the material to be etched. A ligand-exchange reaction is then performed in order to remove the etchant material layer and the atoms bonded to the etchant material layer. With controlled parameters in conjunction with the etchant species, a designed atomic scale thickness is removed by each cycle of the ALE process. The ALE processes are repeated until a desired amount of material is removed from the material to be etched. In some embodiments, the ALE process in FIGS. 11A-11D may also be referred to as quasi-ALE process.

The high-k gate dielectric layers 214 each has a thickness T1 as shown in FIG. 11A. In FIG. 11B, a deposition operation is performed. Specifically, an etchant material layer 310 is formed over and in the high-k gate dielectric layers 214 in the gate via openings O1 and O2. The deposition of the etchant material layer 310 may include placing the wafer including the semiconductor device 100 into an ALE processing chamber and providing (or introducing) a reaction gas A1 into the ALE processing chamber, such that surface layers of the high-k gate dielectric layers 214 adsorb etch materials in the reaction gas A1. In the scenarios that the high-k gate dielectric layers 214 include Hf (e.g., HfO₂), the reaction gas A1 may include a fluoride gas, such as HF, WF₆, NF₃, the like, or combinations thereof. The fluorine elements in the reaction gas A1 may be absorbed by the high-k gate dielectric layers 214 and are bond to the Hf elements of the high-k gate dielectric layers 214 to perform a fluorination reaction. The fluorination of HfO₂ to HfF₄ by HF also produces H₂O gas. Therefore, the etchant material layer 310 may include fluorine elements and the Hf elements (e.g., HfF₄). After the deposition of the etchant material layer 310, the surface layers of the high-k gate dielectric layers 214 adsorbs elements of the etchant material layer 310.

In some embodiments, in the etching process ET, a wafer chuck for supporting the wafer including the semiconductor device 100 may be at a processing temperature in a range of the room temperature to about 100 Celsius degrees. If the processing temperature is higher than about 100 Celsius degrees, the etchant material layer 310 may be too deep into the high-k gate dielectric layers 214, even reaches to the work function metal layer 216, and the work function metal layer 216 may be damaged. In some embodiments, during providing the reaction gas A1, a pressure in the ALE processing chamber may be in a range of 1 mTorr to about 1000 mTorr. In some embodiments, a time duration for introducing the reaction gas A1 is in a range of about 0.1 seconds to about 10 seconds for ensuring that the reaction is self-limiting and in the saturation state.

In some embodiments, the semiconductor base portions 112 and the isolation structures 130 are more inactive to the etchant material layer 310 than the high-k gate dielectric layers 214 are, such that the reaction gas A1 may not cause reaction between the semiconductor base portions 112 and the elements of the etchant material layer 310 and between the isolation structures 130 and the elements of the etchant material layer 310, and therefore not remove the semiconductor base portions 112 and the isolation structures 130. Through the configuration, the semiconductor base portions 112 and the isolation structures 130 may act etch masks in the etching process ET. In other words, the semiconductor base portions 112 and the isolation structures 130 have higher etch resistances to the etching process ET than the high-k gate dielectric layers 214.

Reference is made to FIG. 11C. After the process shown in FIG. 11B, the residual reaction gas A1 is discharged from the ALE processing chamber for a period of time. To more effectively discharge the residual reaction gas A1 from the ALE processing chamber, purge gas may be injected into the ALE processing chamber during this purging period, wherein the purge gas may include a substantially inert gas such as N₂, Ar, He, or similar inert gases. In some embodiments, a time duration for purging the reaction gas A1 is in a range of about 1 second to about 30 seconds for ensuring the residual reaction gas A1 is out of the ALE processing chamber.

Reference is made to FIGS. 11C and 11D. An etching operation is performed. Specifically, an etching gas A2 is then provided (or introduced) into the ALE processing chamber to activate ligand-exchange reactions between the etching gas A2 and the etchant material layer 310, thereby removing the etchant material layer 310 from the high-k gate dielectric layers 214. In the scenarios that the etchant material layer 310 includes fluorine elements and the Hf elements, the etching gas A2 may include a chlorine-containing gas, such as (CH₃)₂AlCl, BCl₃, TiCl₄, SiCl₄, the like, or combinations thereof. The chlorine atoms in the etching gas A2 may replace the fluorine atoms in the etchant material layer 310 (e.g., the ligand-exchange reactions between F and Cl). For example, the ligand-exchange reactions involve F/Cl exchange to produce HfCl₄ and TiF₄ gases. Therefore, the etchant material layers 310 are removed (or etched) from the high-k gate dielectric layers 214. As such, the thickness T1′ of the high-k gate dielectric layers 214 is reduced as shown in FIG. 11D. After the ligand-exchange reactions, a HfCl₃ layer may be bond to an exposed surface of a remaining portion of the high-k gate dielectric layers 214.

In some embodiments, a thermal process without plasma is performed during introducing the etching gas A2 into the ALE processing chamber (e.g., during the etching operation). The wafer chuck for supporting the wafer including the semiconductor device 100 may be at a processing temperature in a range of about 200 Celsius degrees to about 500 Celsius degrees. Specifically, in some embodiments, the processing temperature is greater than about 250 Celsius degrees and lower than about 500 Celsius degrees. That is, the processing temperature of the etching operation is higher than the processing temperature of the deposition operation. The efficiency is increased with a rise in processing temperature due to the activation energy of the etching gas A2 (e.g., chlorine elements). In some embodiments, during providing the etching gas A2, a pressure in the ALE processing chamber may be in a range of 1 mTorr to about 1000 mTorr.

In some other embodiments, the etching operation is performed in a plasma chamber with a bias power, which may be supplied to the wafer chunk that supports the wafer including the semiconductor device 100. In some embodiments, a bias power during the etching operation may be greater than a bias power during the deposition operation. For example, in the deposition operation, the wafer chunk is not bias, and thus the deposition operation is performed without plasma. In some embodiments, during the etching operation with plasma, an Ar flow is introduced into the plasma chamber. In some embodiments, during the etching operation with plasma, the wafer chuck may be at a processing temperature in a range of about 200 Celsius degrees to about 250 Celsius degrees. If the processing temperature is higher than about 250 Celsius degrees, the plasma may damage the structure of the semiconductor device 100; if the processing temperature is lower than about 200 Celsius degrees, the etchant material layer 310 may not be removed.

In some embodiments, the plasma process may be performed with a suitable angle based on the height of the gate via openings O1 and O2. For example, the plasma process may be performed in a direction normal to a top surface of the dielectric structure 270 with argon ions. Through the operation, portions of the high-k gate dielectric layers 214 uncovered by the semiconductor base portions 112 or the isolation structures 130 are thinned by the ALE process ET1, and portions of the high-k gate dielectric layers 214 covered by the semiconductor base portions 112 or the isolation structures 130 protected from being thinned.

In some embodiments, a time duration for introducing the etching gas A2 is in a range of about 0.1 seconds to about 10 seconds. The time duration for introducing the etching gas A2 depends on the removal thickness of the etchant material layer 310. For example, with longer time duration (e.g., longer than about 2 seconds to about 10 seconds), the removal thickness of the etchant material layer 310 is increased. That is, the removal thickness of the etchant material layer 310 can be tuned by controlling the time duration for introducing the etching gas A2. Therefore, the thickness reduction of the etching process ET can be controlled precisely by tuning the time duration of the etching operation.

Reference is made to FIGS. 11D and 11E. After the process shown in FIG. 11D, the residual etching gas A2 is discharged from the ALE processing chamber for a period of time. To more effectively discharge the residual etching gas A2 from the ALE processing chamber, purge gas may be injected into the ALE processing chamber during this purging period, wherein the purge gas may include a substantially inert gas such as N₂, Ar, He, or similar inert gases. In some embodiments, a time duration for purging the etching gas A2 is in a range of about 1 second to about 30 seconds for ensuring the residual etching gas A2 is out of the ALE processing chamber.

The operations in FIGS. 11A-11E are repeated. For example, a next etchant material layer is deposited over the structure of FIG. 11E. The deposition of the etchant material layer may be similar to or the same as the deposition operation shown in FIG. 11B. The residual reaction gas is then purged as shown in FIG. 11C. An etching operation similar to or the same as the etching operation shown in FIG. 11D is then performed to remove the etchant material layer, and the residual etching gas is then purged as shown in FIG. 11E.

The etching process ET may be cycled until the portions of the high-k gate dielectric layers 214 exposed by the gate via openings O1 and O2 are removed. For example, the etching process ET may be repeated until a surface of the work function metal layer 216 is exposed. The work function metal layer 216 is more inactive to the etchant material layer 310 than the high-k gate dielectric layers 214 are, such that the etching operation may not cause reaction on the work function metal layer 216. Through the configuration, the work function metal layer 216 may act as an etch stop layer in the etching process ET. In other words, the etching process ET has a higher etch resistance to the etching process ET than the high-k gate dielectric layers 214. Therefore, the etching process ET prevents the work function metal layer 216 from being etched and damaged. In some embodiments, in each cycle of the etching process ET, the etchant material layer 310 may be deposited by the same gases and gas doses. Alternatively, in some other embodiments, the etchant material layer 310 may be deposited using suitable gases and gas doses that are not the same.

Reference is made to FIGS. 10A-10B. Backside gate vias 282, 284 and backside source/drain vias 286 are formed in the openings O1, O2, and O3 (see FIG. 9A-9B), respectively. Formation of the backside gate via contacts 262, 264 and the backside source/drain vias 266 includes depositing one or more metal materials overfilling the openings O1, O2, and O3, and then performing a CMP process to remove excessive metal materials outside the openings O1, O2, and O3.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the atomic layer etching process provides a precise control over the etching of the high-k gate dielectric layer. Further, the etching operation of the atomic layer etching process is inactive to the work function metal layer, preventing the work function metal layer from being over etched and/or damaged, which may cause threshold voltage shift issues and/or material degradation issues. Therefore, the electrical performance of the gate structure of the bottom transistor can be improved.

According to some embodiments, a method includes providing a complementary FET over a substrate. The complementary FET includes a bottom transistor over a semiconductor base portion of the substrate, and a top transistor over the bottom transistor. A first gate structure of the bottom transistor is in contact with a second gate structure of the top transistor. The substrate is thinned down to expose the semiconductor base portion. A gate via opening is formed in the semiconductor base portion to expose a high-k gate dielectric layer of the first gate structure of the bottom transistor. A deposition operation is performed to form an etchant material layer in the gate via opening and in the high-k gate dielectric layer. An etching operation is performed to remove the etchant material layer. The deposition operation and the etching operation are repeatedly performed until a work function metal layer of the first gate structure is exposed. A backside gate via is formed in the gate via opening.

According to some embodiments, a method includes forming a complementary FET over a substrate. The complementary FET includes a bottom transistor including a first gate structure and a top transistor over the bottom transistor. The first gate structure includes a high-k gate dielectric layer and a work function metal layer over the high-k gate dielectric layer. The substrate is removed. A dielectric structure is deposited to cover a backside of the bottom transistor. A gate via opening is formed in the dielectric structure to expose the high-k gate dielectric layer. An atomic layer etching process is performed to remove the high-k gate dielectric layer exposed by the gate via opening, including introducing a fluoride gas on the high-k gate dielectric layer; introducing a chlorine-containing gas on the high-k gate dielectric layer after introducing the fluoride gas on the high-k gate dielectric layer; and repeating introducing the fluoride gas and introducing the chlorine-containing gas on the high-k gate dielectric layer. A backside gate via is formed in the gate via opening.

According to some embodiments, a method includes forming an isolation structure over a substrate. The isolation structure laterally surrounds a semiconductor base portion of the substrate. A complementary FET is formed over the isolation structure. The complementary FET includes a bottom transistor over the semiconductor base portion and the isolation structure; and a top transistor over the bottom transistor. The substrate is removed to expose the isolation structure. A gate via opening is formed in the isolation structure to expose a high-k gate dielectric layer of a gate structure of the bottom transistor. A fluorination reaction is performed to the high-k gate dielectric layer exposed by the gate via opening. A ligand-exchange reaction is performed to the high-k gate dielectric layer after performing the fluorination reaction. A processing temperature for performing the ligand-exchange reaction is higher than a processing temperature for performing the fluorination reaction. The fluorination reaction and the ligand-exchange reaction are repeatedly performed until a work function metal layer of the gate structure of the bottom transistor is exposed by the gate via opening. A backside gate via is formed in the gate via opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a complementary FET over a substrate, wherein the complementary FET comprises:
a bottom transistor over a semiconductor base portion of the substrate; and
a top transistor over the bottom transistor, wherein a first gate structure of the bottom transistor is in contact with a second gate structure of the top transistor;
thinning down the substrate to expose the semiconductor base portion;
forming a gate via opening in the semiconductor base portion to expose a high-k gate dielectric layer of the first gate structure of the bottom transistor;
performing a deposition operation to form an etchant material layer in the gate via opening and in the high-k gate dielectric layer;
performing an etching operation to remove the etchant material layer;
repeating performing the deposition operation and the etching operation until a work function metal layer of the first gate structure is exposed; and
forming a backside gate via in the gate via opening.

2. The method of claim 1, wherein the etching operation is performed with plasma.

3. The method of claim 1, wherein the deposition operation is performed without plasma.

4. The method of claim 1, wherein a processing temperature of the etching operation is higher than a processing temperature of the deposition operation.

5. The method of claim 1, wherein a time duration of the deposition operation is in a range of about 0.1 seconds to about 10 seconds.

6. The method of claim 1, wherein a time duration of the etching operation is in a range of about 0.1 seconds to about 10 seconds.

7. The method of claim 1, wherein the etchant material layer includes fluorine elements and Hf elements.

8. The method of claim 1, wherein the semiconductor base portion is more inactive to the etchant material layer than the high-k gate dielectric layer is.

9. The method of claim 1, wherein the work function metal layer is more inactive to the etchant material layer than the high-k gate dielectric layer is.

10. A method comprising:
forming a complementary FET over a substrate, wherein the complementary FET comprises:
a bottom transistor comprising a first gate structure, wherein the first gate structure comprises:
a high-k gate dielectric layer; and
a work function metal layer over the high-k gate dielectric layer; and
a top transistor over the bottom transistor;
removing the substrate;
depositing a dielectric structure to cover a backside of the bottom transistor;
forming a gate via opening in the dielectric structure to expose the high-k gate dielectric layer;
performing an atomic layer etching process to remove the high-k gate dielectric layer exposed by the gate via opening, comprising:
introducing a fluoride gas on the high-k gate dielectric layer;
introducing a chlorine-containing gas on the high-k gate dielectric layer after introducing the fluoride gas on the high-k gate dielectric layer; and
repeating introducing the fluoride gas and introducing the chlorine-containing gas on the high-k gate dielectric layer; and
forming a backside gate via in the gate via opening.

11. The method of claim 10, wherein the fluoride gas comprises HF, WF₆, NF₃, or combinations thereof.

12. The method of claim 10, wherein the chlorine-containing gas comprises (CH₃)₂AlCl, BCl₃, TiCl₄, SiCl₄, or combinations thereof.

13. The method of claim 10, wherein a processing temperature for introducing the fluoride gas is in a range of a room temperature to about 100 Celsius degrees.

14. The method of claim 10, wherein a processing temperature for introducing the chlorine-containing gas is greater than about 250 Celsius degrees and lower than about 500 Celsius degrees.

15. The method of claim 14, wherein introducing the chlorine-containing gas is performed without plasma.

16. The method of claim 10, further comprising:
tuning a time duration for introducing the chlorine-containing gas to control a removal thickness of the high-k gate dielectric layer.

17. A method comprising:
forming an isolation structure over a substrate, wherein the isolation structure laterally surrounds a semiconductor base portion of the substrate;
forming a complementary FET over the isolation structure, wherein the complementary FET comprises:
a bottom transistor over the semiconductor base portion and the isolation structure; and
a top transistor over the bottom transistor;
removing the substrate to expose the isolation structure;
forming a gate via opening in the isolation structure to expose a high-k gate dielectric layer of a gate structure of the bottom transistor;
performing a fluorination reaction to the high-k gate dielectric layer exposed by the gate via opening;
performing a ligand-exchange reaction to the high-k gate dielectric layer after performing the fluorination reaction, wherein a processing temperature for performing the ligand-exchange reaction is higher than a processing temperature for performing the fluorination reaction;
repeating performing the fluorination reaction and the ligand-exchange reaction until a work function metal layer of the gate structure of the bottom transistor is exposed by the gate via opening; and
forming a backside gate via in the gate via opening.

18. The method of claim 17, wherein performing the fluorination reaction comprises introducing a fluoride gas to the high-k gate dielectric layer.

19. The method of claim 17, wherein performing the ligand-exchange reaction comprises introducing a chlorine-containing gas to the high-k gate dielectric layer.

20. The method of claim 17, wherein the fluorination reaction is performed without plasma.
